(19) United States
(12) Patent Application Publication
(10) Pub. No.: US 2026/0303051 A1
(43) Pub. Date: Oct. 1, 2026

(54) FILTER AND MULTIPLEXER

(71) Applicant: ANIUI ANUKI TECHNOLOGIES CO., LTD., Hefei (CN)

(72) Inventors: Wentao HUANG, Hefei (CN); Chenggong HE, Hefei (CN); Jian NIU, Hefei (CN); Chengjie ZUO, Hefei (CN); Jun HE, Hefei (CN)

(73) Assignee: ANIUI ANUKI TECHNOLOGIES CO., LTD., Hefei (CN)

(21) Appl. No.: 19/147,183

(22) PCT Filed: Nov. 25, 2024
(86) PCT No.: PCT/CN2024/134071

§ 371 Date: Jul. 10, 2025

(30) Foreign Application Priority Data
Dec. 25, 2023 (CN) 202311812237.5

(51) Int. Cl. H03H 7/075; H03H 7/01; H03H 7/46

(52) U.S. Cl. CPC H03H 7/075; H03H 7/1733; H03H 7/1766; H03H 7/46

(57) ABSTRACT

Provided are a filter and a multiplexer. The filter includes a first port, a second port, and at least one filtering unit. Each of the at least one filtering unit includes a π-type LC network and a resonator, the π-type LC network includes at least one first element and at least two second elements. Each first element of the at least one first element is connected in series between the first port and the second port. A first end of at least one second element is connected between the first port and a first end of the first element. A first end of at least one second element is connected between the second port and a second end of the first element. Second ends of the at least two second elements are connected to each other and then connected to the resonator.

### CROSS REFERENCE TO RELATED APPLICATIONS

This application is a National Stage Application filed under 35 U.S.C. 371 based on International Patent Application No. PCT/CN2024/134071, filed on Nov. 25, 2024, which claims priority to Chinese Patent Application No. 202311812237.5 filed with the China National Intellectual Property Administration (CNIPA) on Dec. 25, 2023, the disclosure of both of which are incorporated herein by reference in their entirety.

### TECHNICAL FIELD

Embodiments of the present application relate to the technical field of signal processing, for example, a filter and a multiplexer.

### BACKGROUND

In a communication system, signal interference can significantly reduce signal transmission efficiency. A filter can effectively suppress out-of-band signal interference to improve the signal transmission efficiency. In modern communication, there is an increasing demand for filters with the characteristics of low insertion loss and high roll-off.

### SUMMARY

The present application provides a filter and a multiplexer to improve the roll-off characteristic of the filter.

In a first aspect, an embodiment of the present application provides a filter. The filter includes a first port, a second port, and at least one filtering unit.

Each of the at least one filtering unit includes a π-type LC network and a resonator, the π-type LC network includes at least one first element and at least two second elements, the at least one first element is connected in series between the first port and the second port, a first end of at least one second element is connected between the first port and a first end of the first element, a first end of at least one second element is connected between the second port and a second end of the first element, and second ends of the at least two second elements are connected to each other and then connected to the resonator.

Optionally, the π-type LC network includes one first element and two second elements.

The first element includes a first inductive element, and the first inductive element is connected in series between the first port and the second port.

The two second elements include a first capacitive element and a second capacitive element, a first end of the first capacitive element is connected between the first port and a first end of the first element, a first end of the second capacitive element is connected between the second port and a second end of the first element, and a second end of the first capacitive element and a second end of the second capacitive element are connected to each other and then connected to the resonator.

Optionally, the filter includes at least two filtering units, where the at least two filtering units are connected in series between the first port and the second port.

Optionally, the filter further includes at least one third port, where the at least one third port is disposed between adjacent filtering units.

Optionally, transmission zeros of different filtering units correspond to an equal frequency.

Optionally, the filter further includes at least one electromagnetic filtering network, where the at least one electromagnetic filtering network is connected in series between the first port and the second port.

Optionally, the filter includes at least two filtering units, where in response to the at least two filtering units being connected in series between the first port and the second port, the at least one electromagnetic filtering network is connected between adjacent filtering units.

Optionally, each of the at least one electromagnetic filtering network includes a second inductive element, and the second inductive element is connected in series between the first port and the second port.

Optionally, each of the at least one electromagnetic filtering network further includes a third capacitive element, and the third capacitive element and the second inductive element are connected to each other in series and/or in parallel.

In a second aspect, an embodiment of the present application further provides a multiplexer. The multiplexer includes the filter described in the first aspect.

### BRIEF DESCRIPTION OF DRAWINGS

FIG. 1 is a structural diagram of a filter according to an embodiment of the present application;

FIG. 2 is a structural diagram of another filter according to an embodiment of the present application;

FIG. 3 is a structural diagram of an LC filter according to an embodiment;

FIG. 4 is a graph showing performance comparison of different filters according to an embodiment of the present application;

FIG. 5 is a structural diagram of another filter according to an embodiment of the present application;

FIG. 6 is a structural diagram of another filter according to an embodiment of the present application;

FIG. 7 is a structural diagram of another filter according to an embodiment of the present application;

FIG. 8 is a structural diagram of another filter according to an embodiment of the present application;

FIG. 9 is a structural diagram of another filter according to an embodiment of the present application;

FIG. 10 is a structural diagram of another filter according to an embodiment of the present application; and

FIG. 11 is a structural diagram of a multiplexer according to an embodiment of the present application.

### DETAILED DESCRIPTION

The present application is described in detail hereinafter in conjunction with the drawings and embodiments. The embodiments described herein are only intended to illustrate the present application. For ease of description, only part, not all, of structures related to the present application are illustrated in the drawings.

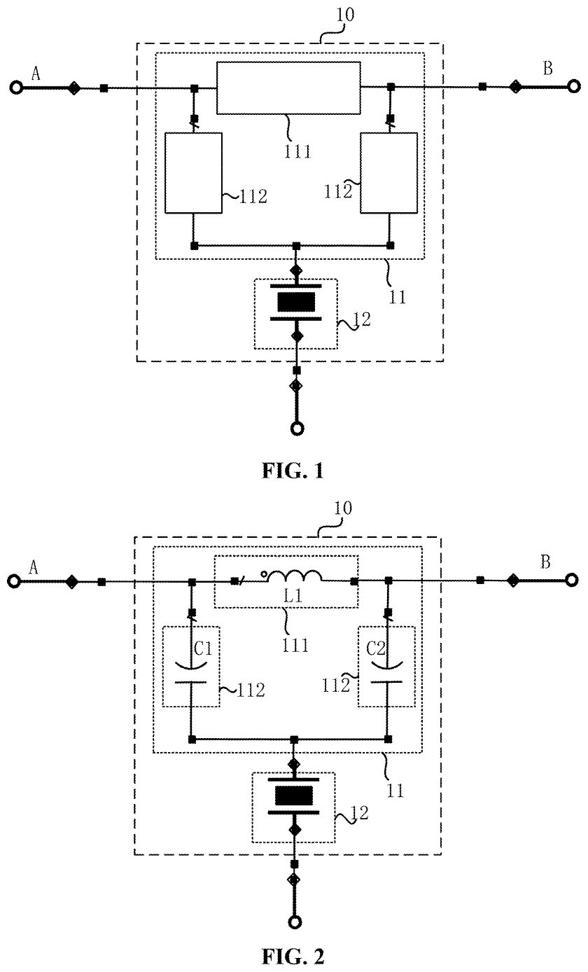

FIG. 1 is a structural diagram of a filter according to an embodiment of the present application. As shown in FIG. 1, the filter includes a first port A, a second port B, and at least one filtering unit 10. Each of the at least one filtering unit 10 includes a π-type LC network 11 and a resonator 12. The π-type LC network 11 includes at least one first element 111 and at least two second elements 112. The at least one first element 111 is connected in series between the first port A and the second port B. A first end of at least one second element 112 is connected between the first port A and a first end of the first element 111. A first end of at least one second element 112 is connected between the second port B and a second end of the first element 111. Second ends of the at least two second elements 112 are connected to each other and then connected to the resonator 12.

Optionally, the π-type LC network 11 includes a capacitive element and an inductive element. The capacitive element and the inductive element are used for forming a π-type LC filtering network to filter signals. The π-type LC network 11 may be a low-pass filtering network. For example, the first element 111 may include the inductive element, and each second element 112 of the at least two second elements 112 may include the capacitive element. When one first element 111 and two second elements 112 are provided, the first element 111 and the second elements 112 may form a third-order low-pass filtering network. When the passband of the π-type LC network 11 transitions to the stopband, the Z parameter of the π-type LC network 11 has the maximum point, and the Y parameter of the π-type LC network 11 does not have the minimum point. In this case, no transmission zero exists in the stopband of the filter. The Z parameter refers to the impedance parameter of the π-type LC network 11, and the Y parameter refers to the admittance parameter of the π-type LC network 11.

The resonator 12 may be an acoustic resonator. For example, the resonator 12 may be at least one of a bulk acoustic wave (BAW) resonator, a surface acoustic wave (SAW) resonator, or a film bulk acoustic resonator (FBAR) filter. The resonator 12 has a band-pass characteristic and has a transmission zero in the adjacent band on the high-frequency side of a passband. That is, regarding the transmission characteristics of the resonator 12, the Z parameter has the maximum point in the adjacent band on the high-frequency side of the passband, allowing the resonator 12 to have a very strong suppression effect at the frequency corresponding to the transmission zero. Thus, the resonator 12 has a very large roll-off slope at the frequency corresponding to the transmission zero. After the second ends of the at least two second elements 112 are connected to each other, the second ends of the at least two second elements 112 are connected to the resonator 12 so that the resonator 12 is connected in series to the π-type LC network 11. In this case, the Z parameter of the filter is the sum of the Z parameter of the resonator 12 and the Z parameter of the π-type LC network 11. After the Z parameter of the π-type LC network 11 and the Z parameter of the resonator 12 are added, the Z parameter of the filter has the maximum point in the adjacent band on the high-frequency side of a passband, and the Y parameter of the filter has the minimum point. Thus, the roll-off slope in the adjacent band on the high-frequency side of the passband can be increased, and the suppression of the adjacent band on the high-frequency side of the passband of the filter is improved, thereby improving the filtering performance of the filter. In addition, the resonator 12 has the band-pass characteristic and has the minimum point of the Z parameter in the passband. That is, the resonator 12 has the maximum point of the Y parameter in the passband. When the Z parameter of the resonator 12 and the Z parameter of the π-type LC network 11 are added, the frequency difference between the zero and pole of the filter can be reduced based on the original frequency difference between the zero and pole of the resonator 12. Thus, the roll-off slope between the passband and the high-frequency side can be increased, and the suppression of the adjacent band on the high-frequency side of the passband of the filter is improved, thereby improving the filtering performance of the filter. In addition, on the high-frequency side of the passband of the resonator 12, the value of the Z parameter of the π-type LC network 11 and the value of the Z parameter of the resonator 12 have opposite signs, allowing the sum of the Z parameter of the π-type LC network 11 and the Z parameter of the resonator 12 to generate an additional maximum point in the range of the adjacent band on the high-frequency side of the passband. That is, in the filtering unit 10, an additional transmission zero is generated in the adjacent band on the high-frequency side of the passband of the filtering unit 10. Thus, the roll-off slope in the adjacent band on the high-frequency side of the passband can be increased, and the suppression of the adjacent band on the high-frequency side of the passband of the filter is improved, thereby improving the filtering performance of the filter. The adjacent band may refer to a frequency band above or below the passband, and a transition band between the adjacent band and the passband may even be only 0 MHz to tens of MHz. In addition, the bandwidth of the adjacent band indicates a frequency band range over 10% of the central frequency of the passband.

After one end of the resonator 12 is connected in series to the π-type LC network 11, the other end of the resonator 12 is used as the port of the filter and can be connected to an external circuit. Thus, the filter can be connected to different types of external circuits, thereby increasing the application range of the filter.

In this embodiment, the resonator in the filtering unit is configured to be connected in series to the π-type LC network so that the Z parameter of the resonator and the Z parameter of the π-type LC network are added. Thus, two transmission zeros can be formed in the range of the adjacent band on the high-frequency side of the passband of the filter. In addition, the frequency difference between the zero and pole of the filter can be reduced. Accordingly, the roll-off slope in the adjacent band on the high-frequency side of the passband of the filter is significantly increased, and the suppression of the adjacent band on the high-frequency side of the passband of the filter is significantly improved, thereby improving the filtering performance of the filter.

FIG. 2 is a structural diagram of another filter according to an embodiment of the present application. As shown in FIG. 2, the π-type LC network 11 includes one first element 111 and two second elements 112. The first element 111 includes a first inductive element L1, and the first inductive element L1 is connected in series between the first port A and the second port B; and/or the two second elements 112 include a first capacitive element C1 and a second capacitive element C2, a first end of the first capacitive element C1 is connected between the first port A and a first end of the first element 111, a first end of the second capacitive element C2 is connected between the second port B and a second end of the first element 111, and a second end of the first capacitive element C1 and a second end of the second capacitive element C2 are connected to each other and then connected to the resonator 12.

Optionally, FIG. 2 exemplarily shows that the first element 111 includes the first inductive element L1, and the two second elements 112 include the first capacitive element C1 and the second capacitive element C2. The first inductive element L1 is connected in series between the first port A and the second port B. In addition, the first end of the first capacitive element C1 is connected between the first port A and the first end of the first element 111, and the first end of the second capacitive element C2 is connected between the second port B and the second end of the first element 111. In this manner, the first inductive element L1, the first capacitive element C1, and the second capacitive element C2 form a third-order low-pass filtering network. In addition, the second end of the first capacitive element C1 and the second end of the second capacitive element C2 are connected to each other and then connected to the resonator 12. Thus, the resonator 12 is connected in series to the π-type LC network 11 so that the Z parameter of the resonator 12 and the Z parameter of the π-type LC network 11 can be added. Accordingly, two transmission zeros can be formed in the range of the adjacent band on the high-frequency side of the passband of the filter. In addition, the frequency difference between the zero and pole of the filter can be reduced. Thus, the roll-off slope in the adjacent band on the high-frequency side of the passband of the filter is significantly increased, and the suppression of the adjacent band on the high-frequency side of the passband of the filter is significantly improved, thereby improving the filtering performance of the filter.

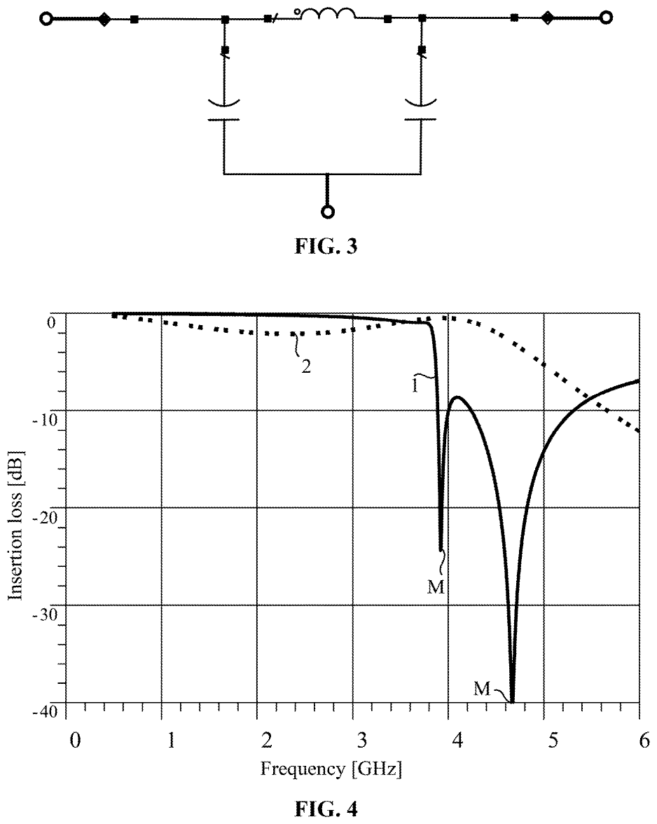

For example, FIG. 3 is a structural diagram of an LC filter according to an embodiment. The specific structure of the LC filter is the same as that of the π-type LC network 11 in FIG. 2. FIG. 4 is a graph showing performance comparison of different filters according to an embodiment of the present application. The abscissa represents a frequency, and the ordinate represents insertion loss. Curve 1 is the frequency-insertion loss curve of the filter provided in FIG. 2, and curve 2 is the frequency-insertion loss curve of the filter provided in FIG. 3. As shown in FIG. 4, curve 1 forms the two transmission zeros M in the range of the adjacent band on the high-frequency side of the passband. The suppression level of one of the two transmission zeros reaches below −20 dB, and the suppression level of the other transmission zero reaches around −40 dB with a very steep roll-off slope. However, curve 2 forms no transmission zero in the range of the adjacent band on the high-frequency side of the passband, showing a relatively low suppression level and a relatively gentle roll-off slope. Therefore, it can be seen that the resonator 12 is connected in series to the LC filter provided in FIG. 3 so that the two transmission zeros can be formed in the range of the adjacent band on the high-frequency side of the passband of the filter. Thus, the roll-off slope in the adjacent band on the high-frequency side of the passband of the filter can be significantly increased, and the suppression of the adjacent band on the high-frequency side of the passband of the filter is significantly improved, thereby improving the filtering performance of the filter.

In other embodiments, the first element 111 may include multiple inductive elements. The multiple inductive elements may be connected in series and/or in parallel. The second element 112 may include at least multiple capacitive elements. In addition to the multiple capacitive elements, the second element 112 may also include an inductive element. The at least multiple capacitive elements may be connected in series and/or in parallel. Alternatively, the first element 111 and/or the second element 112 may also include a resistive element. The resistive element is connected in series or parallel to the inductive element and/or the capacitive elements to adjust the resonant frequency of the π-type LC network 11. Each of the capacitive elements may be a capacitor element or parasitic capacitance generated between different elements. The resistance value of each of the capacitive elements may be set as needed.

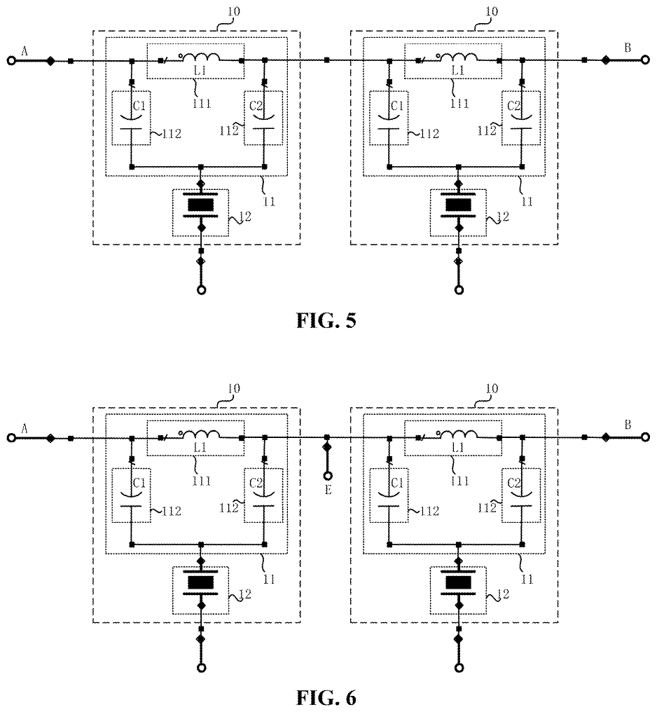

FIG. 5 is a structural diagram of another filter according to an embodiment of the present application. As shown in FIG. 5, the filter includes at least two filtering units 10 connected in series between the first port A and the second port B.

Optionally, FIG. 5 exemplarily shows that the filter includes two filtering units 10 connected in series between the first port A and the second port B. When the at least two filtering units 10 are connected in series between the first port A and the second port B, each of different filtering units 10 can generate two transmission zeros in the adjacent band on the high-frequency side of the passband of the filter. Thus, each of the at least two filtering units 10 can significantly increase the roll-off slope in the adjacent band on the high-frequency side of the passband so that the suppression of the adjacent band on the high-frequency side of the passband of the filter can be improved, thereby improving the filtering performance of the filter.

For example, transmission zeros of the different filtering units 10 correspond to an equal frequency.

Optionally, the π-type LC networks 11 and the resonators 12 in the different filtering units 10 may have the same parameters so that the transmission zeros of the different filtering units 10 correspond to the equal frequency. In this case, the different filtering units 10 have the same passband frequency and form the transmission zeros at the same frequency. Thus, the roll-off slope in the adjacent band on the high-frequency side of the passband can be increased. For example, in the different filtering units 10, the π-type LC networks 11 have the same elements, and the elements at the same position also have the same parameter. In addition, the resonators 12 in the different filtering units 10 have the same parameter so that the resonant frequencies of the different filtering units 10 can be equal to each other.

In other embodiments, the transmission zeros of different filtering units 10 may be configured to correspond to different frequencies so that the filter has multiple transmission zeros in the range of the adjacent band on the high-frequency side of the passband. Compared with the filtering unit 10 with the two transmission zeros, the filter with the multiple transmission zeros can also increase the roll-off slope in the adjacent band on the high-frequency side of the passband. For example, in the different filtering units 10, the π-type LC networks 11 may have different elements, and/or the elements at the same position have different parameters, and/or the resonators 12 in the different filtering units 10 have different parameters.

In other embodiments, the filter may include multiple filtering units 10 connected in series between the first port A and the second port B.

FIG. 6 is a structural diagram of another filter according to an embodiment of the present application. As shown in FIG. 6, the filter further includes at least one third port E disposed between adjacent filtering units 10.

Optionally, FIG. 6 exemplarily shows that the filter includes the two filtering units 10, and one third port E is disposed between the two filtering units 10. The third port E may be used for connecting an external circuit so that the filter can be connected to different types of external circuits, thereby increasing the application range of the filter. Additionally, the third port E may also be connected to an element with equivalent high impedance. Thus, the third port E is equivalent to an open circuit so that the filter is applicable to different scenarios.

When the filter includes the multiple filtering units 10, the third port E may be disposed between two adjacent filtering units 10, or the third port E may be disposed between one of the filtering units 10 and the first port A and/or the second port B. In this case, the filter may include multiple third ports E. The third port E may be disposed between spaced filtering units 10. In this case, the filter may include at least one third port E.

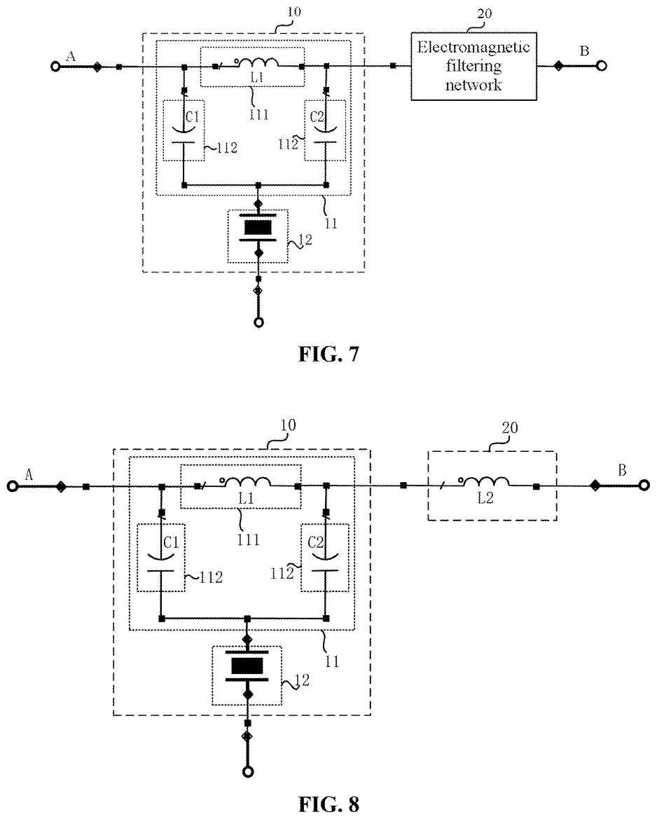

FIG. 7 is a structural diagram of another filter according to an embodiment of the present application. As shown in FIG. 7, the filter further includes at least one electromagnetic filtering network 20 connected in series between the first port A and the second port B.

Optionally, the electromagnetic filtering network 20 may include an inductive element and/or a capacitive element. When the electromagnetic filtering network 20 includes only the inductive element or the capacitive element, the electromagnetic filtering network 20 can compensate for the π-type LC network 11, thereby reducing the insertion loss of the π-type LC network 11 and improving the filtering performance of the filter. When the electromagnetic filtering network 20 includes both the inductive element and the capacitive element, the electromagnetic filtering network 20 can adjust the passband of the filter so that the filter has a relatively wide passband.

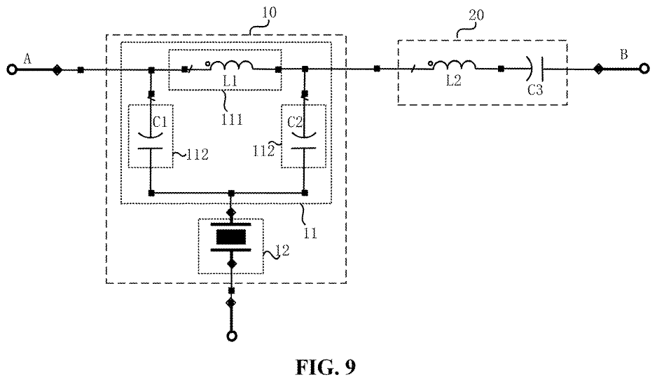

For example, FIG. 8 is a structural diagram of another filter according to an embodiment of the present application. As shown in FIG. 8, the electromagnetic filtering network 20 includes a second inductive element L2 connected in series between the first port A and the second port B.

Optionally, FIG. 8 exemplarily shows that the electromagnetic filtering network 20 includes the second inductive element L2 connected in series between the second port B and the filtering unit 10. When the first element 111 includes the inductive element and the second element 112 includes the capacitive element, the second inductive element L2 can compensate for the insertion loss of the π-type LC network 11, thereby improving the filtering performance of the filter.

In other embodiments, the electromagnetic filtering network 20 may include only the capacitive element. The capacitive element is provided so that the frequency of the filtering unit 10 can be adjusted. In addition, the electromagnetic filtering network 20 can be used as a high-pass filtering network in the filter to adjust the passband of the filter.

In other embodiments, FIG. 9 is a structural diagram of another filter according to an embodiment of the present application. As shown in FIG. 9, the electromagnetic filtering network 20 further includes a third capacitive element C3, and the third capacitive element C3 and the second inductive element L2 are connected to each other in series and/or in parallel.

Optionally, FIG. 9 exemplarily shows that the third capacitive element C3 is connected in series to the second inductive element L2. The second inductive element L2 and the third capacitive element C3 can form a filtering network to adjust the passband of the filter, allowing the filter to have a relatively wide passband. When the filter includes both the electromagnetic filtering network 20 and the filtering unit 10, it can be ensured that the filter has a relatively wide passband and the roll-off slope in the adjacent band on the high-frequency side of the passband of the filter can be increased. Thus, the suppression of the adjacent band on the high-frequency side of the passband of the filter is significantly improved, thereby improving the filtering performance of the filter.

In other embodiments, the second inductive element L2 and the third capacitive element C3 may be configured to be connected in parallel to adjust the performance of the filter according to the needs of the filter. Alternatively, when at least one of the number of second inductive elements L2 or the number of third capacitive elements C3 is multiple, the second inductive element L2 and the third capacitive element C3 may be connected in series and/or parallel as needed.

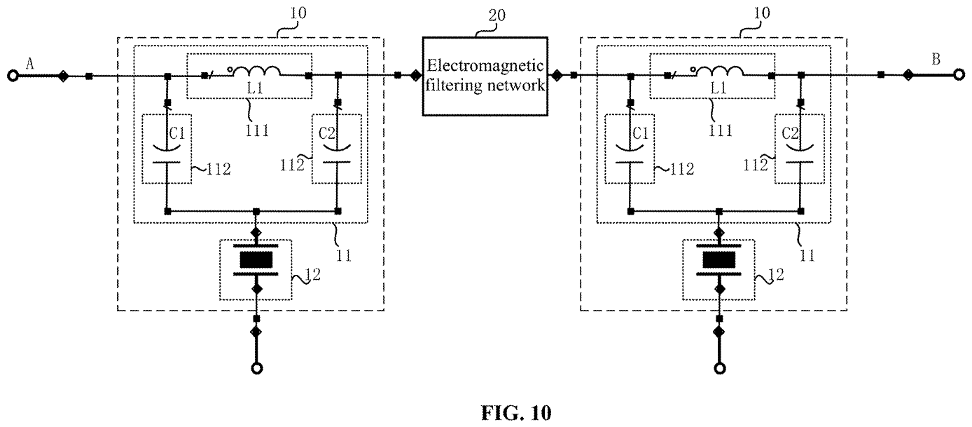

FIG. 10 is a structural diagram of another filter according to an embodiment of the present application. As shown in FIG. 10, when the filter includes the at least two filtering units 10 connected in series between the first port A and the second port B, at least one electromagnetic filtering network 20 is connected between adjacent filtering units 10.

Optionally, FIG. 10 exemplarily shows that the filter includes the two filtering units 10, and the electromagnetic filtering network 20 is connected between the two filtering units 10. Thus, the different filtering units 10 can be spaced apart.

In other embodiments, the electromagnetic filtering network 20 may be disposed between the first port A and one of the filtering units 10 or between the second port B and one of the filtering units 10.

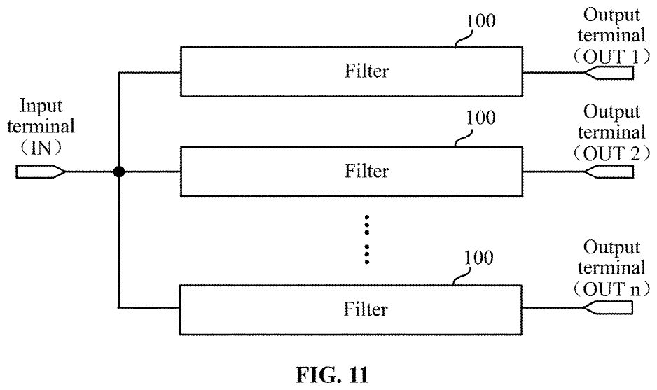

An embodiment of the present application further provides a multiplexer. FIG. 11 is a structural diagram of the multiplexer according to an embodiment of the present application. As shown in FIG. 11, the multiplexer includes the filter 100 provided in any embodiment of the present application.

With continued reference to FIG. 11, the multiplexer includes one input terminal IN and at least two output terminals. Each filter 100 is connected in series between the input terminal IN of the multiplexer and any one of the output terminals.

Optionally, FIG. 11 exemplarily shows that the multiplexer includes one input terminal IN and n output terminals that are OUT1, OUT2, . . . , and OUTn, respectively. Each filter 100 is connected in series between the input terminal IN and one of the output terminals. For example, the first filter 100 is connected in series between the input terminal IN and the first output terminal OUT1, the second filter 100 is connected in series between the input terminal IN and the second output terminal OUT2, and so on. Since the multiplexer has the filter 100 provided in any embodiment of the present application, the multiplexer has the same beneficial effects as the filter 100. Thus, the roll-off slope in the adjacent band on the low-frequency side of a passband of the multiplexer significantly improves the suppression of the adjacent band on the low-frequency side of the passband of the filter, thereby improving the filtering performance of the filter.

The multiplexer may also include other filters are connected in series between the input terminal IN and any output. These other filters may be low-pass filters, high-pass filters, or band-pass filters.

1. A filter, comprising a first port, a second port, and at least one filtering unit; wherein each of the at least one filtering unit comprises a π-type LC network and a resonator, the π-type LC network comprises at least one first element and at least two second elements, the at least one first element is connected in series between the first port and the second port, a first end of at least one of the at least two second elements is connected between the first port and a first end of the first element, a first end of at least one of the at least two second elements is connected between the second port and a second end of the first element, and second ends of the at least two second elements are connected to each other and then connected to the resonator.

2. The filter according to claim 1, wherein the π-type LC network comprises one first element of the at least one first element and two second elements of the at least two second elements;
wherein the filter satisfies at least one of the following:
the first element comprises a first inductive element, and the first inductive element is connected in series between the first port and the second port; or
the two second elements comprise a first capacitive element and a second capacitive element, a first end of the first capacitive element is connected between the first port and a first end of the first element, a first end of the second capacitive element is connected between the second port and a second end of the first element, and a second end of the first capacitive element and a second end of the second capacitive element are connected to each other and then connected to the resonator.

3. The filter according to claim 1, comprising at least two filtering units, wherein the at least two filtering units are connected in series between the first port and the second port.

4. The filter according to claim 3, further comprising at least one third port, wherein the at least one third port is disposed between adjacent filtering units of the at least two filtering units.

5. The filter according to claim 3, wherein transmission zeros of different filtering units of the at least two filtering units correspond to an equal frequency.

6. The filter according to claim 1, further comprising at least one electromagnetic filtering network, wherein the at least one electromagnetic filtering network is connected in series between the first port and the second port.

7. The filter according to claim 6, comprising at least two filtering units, wherein in response to the at least two filtering units being connected in series between the first port and the second port, the at least one electromagnetic filtering network is connected between adjacent filtering units of the at least two filtering units.

8. The filter according to claim 6, wherein each of the at least one electromagnetic filtering network comprises a second inductive element, and the second inductive element is connected in series between the first port and the second port.

9. The filter according to claim 8, wherein each of the at least one electromagnetic filtering network further comprises a third capacitive element, and the third capacitive element and the second inductive element are configured to be connected to each other in at least one of a serial manner or a parallel manner.

10. A multiplexer, comprising: an input terminal, at least two output terminals, and filters, wherein each of the filters is configured to be connected in series between the input terminal and any one of the at least two output terminals,
wherein the filter comprises a first port, a second port, and at least one filtering unit;
wherein each of the at least one filtering unit comprises a π-type LC network and a resonator, the π-type LC network comprises at least one first element and at least two second elements, the at least one first element is connected in series between the first port and the second port, a first end of at least one of the at least two second elements is connected between the first port and a first end of the first element, a first end of at least one of the at least two second elements is connected between the second port and a second end of the first element, and second ends of the at least two second elements are connected to each other and then connected to the resonator.

11. The filter according to claim 2, comprising at least two filtering units, wherein the at least two filtering units are connected in series between the first port and the second port.

12. The filter according to claim 7, wherein each of the at least one electromagnetic filtering network comprises a second inductive element, and the second inductive element is connected in series between the first port and the second port.

13. The multiplexer according to claim 10, wherein the π-type LC network comprises one first element of the at least one first element and two second elements of the at least two second elements;
wherein the filter satisfies at least one of the following:
the first element comprises a first inductive element, and the first inductive element is connected in series between the first port and the second port; or
the two second elements comprise a first capacitive element and a second capacitive element, a first end of the first capacitive element is connected between the first port and a first end of the first element, a first end of the second capacitive element is connected between the second port and a second end of the first element, and a second end of the first capacitive element and a second end of the second capacitive element are connected to each other and then connected to the resonator.

14. The multiplexer according to claim 10, comprising at least two filtering units, wherein the at least two filtering units are connected in series between the first port and the second port.

15. The multiplexer according to claim 14, further comprising at least one third port, wherein the at least one third port is disposed between adjacent filtering units of the at least two filtering units.

16. The multiplexer according to claim 14, wherein transmission zeros of different filtering units of the at least two filtering units correspond to an equal frequency.

17. The multiplexer according to claim 10, further comprising at least one electromagnetic filtering network, wherein the at least one electromagnetic filtering network is connected in series between the first port and the second port.

18. The multiplexer according to claim 17, comprising at least two filtering units, wherein in response to the at least two filtering units being connected in series between the first port and the second port, the at least one electromagnetic filtering network is connected between adjacent filtering units of the at least two filtering units.

19. The multiplexer according to claim 17, wherein each of the at least one electromagnetic filtering network comprises a second inductive element, and the second inductive element is connected in series between the first port and the second port.

20. The multiplexer according to claim 19, wherein each of the at least one electromagnetic filtering network further comprises a third capacitive element, and the third capacitive element and the second inductive element are configured to be connected to each other in at least one of a serial manner or a parallel manner.
